(19) United States
(12) Patent Application Publication
(10) Pub. No.: US 2013/0207246 A1
(43) Pub. Date: Aug. 15, 2013

(54) Packaging an Integrated Circuit Die

(71) Applicant: Nedyalko Slavov, Zurich (CH)

(72) Inventor: Nedyalko Slavov, Zurich (CH)

(73) Assignee: ST-ERICSSON SA, Plan-les-Ouates (CH)

(21) Appl. No.: 13/816,108

(22) PCT Filed: Aug. 10, 2011
(86) PCT No.: PCT/EP2011/063790

§ 371 Date: Mar. 29, 2013

(30) Foreign Application Priority Data
Aug. 10, 2010 (EP) 10251425.4

(51) Int. Cl. H01L 23/552; H01L 25/00

(52) U.S. Cl. CPC H01L 23/552; H01L 25/00; H01L 25/50
USPC 257/659; 438/107

(57) ABSTRACT

An electronic device (100) comprises an integrated circuit die (130) mounted on a substrate (120). An electrical terminal (134) of the integrated circuit die (130) is coupled to an electrical terminal (124) of the substrate (120) by means of a wire (136) embedded in an electrically non-conductive moulded housing (140). The integrated circuit die (130) is also embedded in the electrically non-conductive moulded housing (140). There is an electrically conductive material (146) on a surface (142) of the moulded housing (140), and a connection means (127) for coupling the electrically conductive material (146) to a reference voltage. The electrically conductive material (146) and the substrate (120) in combination enclose the first integrated circuit die (130) and the first wire (136). There is a second integrated circuit die (150) mounted on the first electrically conductive material (146) and separated from the first wire (136) by the first electrically conductive material (146).

### FIELD OF THE DISCLOSURE

The present disclosure relates to an electronic device, a method of manufacturing an electronic device, and an electronic apparatus comprising an electronic device. In particular, the disclosure relates to packaging an integrated circuit die.

### BACKGROUND TO THE DISCLOSURE

There is a requirement to combine a plurality of integrated circuit dies in a single package in order to reduce size and cost. The different dies may contain different subsystems produced using different integrated circuit technologies optimised for different requirements. For example, different dies may be used for digital circuitry, radio frequency circuitry and memory.

The use of different dies, rather than a common die, enables the use of optimal technology and respectively lowering the price or improving the performance. However, there remains a requirement to minimise the coupling of interference between different dies, particularly where high frequency signals are involved. For example, a highly sensitive radio frequency input can be affected by noise generated by digital circuitry or a power management unit at a level of a few microvolts. As another example, noise can introduce unacceptable jitter to a phase locked loop, and such jitter can mask a desired signal which is frequency or phase modulated onto a carrier. As a further example, high frequency noise coupled to a microphone input can be disruptive if it has a low frequency envelope, with frequencies in the same frequency range as a wanted audio signal.

One way of reducing interference between dies is to mount the dies in separate packages in different areas of a printed circuit board (PCB), and to connect the dies via metal tracks on or in the PCB. The coupling of interference between the dies can be reduced by using a high number of PCB metal layers, including metal layers for shielding. However, such a solution is large and costly, and such PCB interconnections can introduce additional parasitic elements which can compromise high frequency operation.

Another way of reducing interference between dies is to mount the dies on different areas of a common substrate in a common package. Interconnections between the dies can be located within the substrate. Flip-chip technology can be used for coupling the dies to the substrate, rather than using bond wires, as capacitive or inductive coupling of interference between bond wires can occur. However, such a solution employing lateral placement of dies on a common substrate can also be large.

### SUMMARY OF THE PREFERRED EMBODIMENTS

According to a first aspect, there is provided an electronic device comprising: a first integrated circuit die mounted on a substrate; a first wire coupling a first electrical terminal of the first integrated circuit die to a first electrical terminal of the substrate; a first electrically non-conductive moulded housing in which the first wire is embedded; a first electrically conductive material on a surface of the first electrically non-conductive moulded housing; and a first connection means for coupling the first electrically conductive material to a reference voltage.

According to a second aspect, there is provided a method of manufacturing an electronic device, comprising: mounting a first integrated circuit die on a substrate; providing a first wire coupling a first electrical terminal of the first integrated circuit die to a first electrical terminal of the substrate; moulding a first electrically non-conductive moulded housing to embed the first wire; applying a first electrically conductive material to a surface of the first electrically non-conductive moulded housing; and providing a first connection means for coupling the first electrically conductive material to a reference voltage.

By embedding one or more wires in a first moulded housing made of an electrically non-conductive material, and applying a first electrically conductive material to a surface of the first moulded housing, which can be coupled to a reference voltage, the wires can be shielded from external interference, or interference radiated from the wires can be suppressed. This enables wires to be used for interconnection, despite their susceptibility to capacitive or inductive coupling, and also enables the impedance of the wires to be more readily controlled.

The use of wires for interconnection enables the electronic device to be kept compact. This is particularly the case when a plurality of integrated circuit dies are incorporated in the electronic device, for example by stacking the first integrated circuit die with other integrated circuit dies.

The reference voltage may be a ground or a power supply voltage.

The electronic device may comprise a second integrated circuit die. Likewise, the method may comprise providing the electronic device with a second integrated circuit die. The second integrated circuit die may be separated from the first wire and/or the first integrated circuit die by the first electrically conductive material. In other words, the first electrically conductive material may be between a) the first wire and/or the first integrated circuit die and b) the second integrated circuit die. The electronic device may have a second wire coupling a second electrical terminal of the second integrated circuit die to a second electrical terminal of the substrate, in which case the second wire may be separated from the first wire and/or the first integrated circuit die by the first electrically conductive material. In other words, the first electrically conductive material may be between a) the first wire and/or the first integrated circuit die and b) the second wire. These features provide protection against interference between a) the second integrated circuit die and/or the second wire and b) the first integrated circuit die and/or the first wire.

The second integrated circuit die may be mounted on the first electrically conductive material.

The electronic device may comprise: a second wire coupling a second electrical terminal of the second integrated circuit die to a second electrical terminal of the substrate; a second electrically non-conductive moulded housing in which the second wire is embedded; a second electrically conductive material on a surface of the second electrically non-conductive moulded housing; and a second connection means for coupling the second electrically conductive material to the reference voltage. Likewise, the method may comprise: providing a second wire coupling a second electrical terminal of a/the second integrated circuit die to a second electrical terminal of the substrate; moulding a second electrically non-conductive moulded housing to embed the second wire; applying a second electrically conductive material to a surface of the second electrically non-conductive moulded housing; and providing a second connection means for coupling the second electrically conductive material to the reference voltage.

The electronic device may comprise a third wire coupling a third electrical terminal of the second integrated circuit die to the first electrically conductive material. Likewise, the method may comprise providing a third wire coupling a third electrical terminal of the second integrated circuit die to the first electrically conductive material. The third wire may be embedded in the second electrically non-conductive moulded housing. This enables an improved ground connection or supply voltage connection to the second integrated circuit die to be made via the first electrically conductive material. In particular, such connections can have low impedance.

The electronic device may comprise a third integrated circuit die. Likewise, the method may comprise providing the electronic device with a third integrated circuit die. The third integrated circuit die may be separated from the second wire and/or the second integrated circuit die by the second electrically conductive material. The third integrated circuit die may be separated from the first wire and/or the first integrated circuit die by the first electrically conductive material. The third integrated circuit die may additionally or alternatively be separated from the first wire and/or the first integrated circuit die by the second electrically conductive material. In other words, the second electrically conductive material may be between a) the second wire and/or the second integrated circuit die and b) the third integrated circuit die; the second electrically conductive material may be between a) the first wire and/or the first integrated circuit die and b) the third integrated circuit die; and/or the first electrically conductive material may be between a) the first wire and/or the first integrated circuit die and b) the third integrated circuit die.

The electronic device may have a fourth wire coupling a third electrical terminal of the third integrated circuit die to a third electrical terminal of the substrate, in which case the fourth wire may be separated from the second wire and/or the second integrated circuit die by the second electrically conductive material. The fourth wire may be separated from the first wire and/or the first integrated circuit die by the first electrically conductive material. The fourth wire may additionally or alternatively be separated from the first wire and/or the first integrated circuit die by the second electrically conductive material. In other words, the second electrically conductive material may be between a) the second wire and/or the second integrated circuit die and b) the fourth wire; the second electrically conductive material may be between a) the first wire and/or the first integrated circuit die and b) the fourth wire; and/or the first electrically conductive material may be between a) the first wire and/or the first integrated circuit die and b) the fourth wire. This enables a multi-die electronic device to be compact by stacking the first, second and third integrated circuit dies.

The third integrated circuit die may be mounted on the second electrically conductive material.

The electronic device may comprise: a fourth wire coupling a third electrical terminal of a/the third integrated circuit die to a third electrical terminal of the substrate; a third electrically non-conductive moulded housing in which the fourth wire is embedded; a third electrically conductive material on a surface of the third electrically non-conductive moulded housing; and a third connection means for coupling the third electrically conductive material to the reference voltage. Likewise, the method may comprise:

providing a fourth wire coupling a third electrical terminal of a/the third integrated circuit die to a third electrical terminal of the substrate; moulding a third electrically non-conductive moulded housing to embed the fourth wire; applying a third electrically conductive material to a surface of the third electrically non-conductive moulded housing; and providing a third connection means for coupling the third electrically conductive material to the reference voltage. This enables protection against interference to or from the fourth wire.

The electronic device may comprise a fifth wire coupling a fifth electrical terminal of the third integrated circuit die to the second electrically conductive material. Likewise, the method may comprise providing a fifth wire coupling a fifth electrical terminal of the third integrated circuit die to the second electrically conductive material. The fifth wire may be embedded in the third electrically non-conductive moulded housing. This enables an improved ground connection or supply voltage connection to the third integrated circuit die to be made via the second electrically conductive material. In particular, such connections can have low impedance.

The first electrically non-conductive moulded housing may cover the first integrated circuit die. Likewise, in the method, moulding the first electrically non-conductive moulded housing may comprise covering the first integrated circuit die by the first electrically non-conductive moulded housing. The extent to which the first electrically non-conductive moulded housing covers the first integrated circuit die may depend on how the first integrated circuit die is mounted on the substrate. Typically, the first electrically non-conductive moulded housing completely covers the parts of first integrated circuit die not in contact with the substrate. This may mean that the first electrically non-conductive moulded housing completely covers the parts of first integrated circuit die not in contact with the substrate. If there is a gap between the first integrated circuit die and the substrate, the first electrically non-conductive moulded housing may cover the first integrated circuit die in the gap.

Usually, the first electrically conductive material and the substrate on which the first integrated circuit die is mounted enclose the first integrated circuit die and the first wire. This enables improved protection against interference to or from the first integrated circuit die and the first wire.

The second electrically non-conductive moulded housing may cover the second integrated circuit die. Likewise, in the method, moulding the second electrically non-conductive moulded housing may comprise covering the second integrated circuit die by the second electrically non-conductive moulded housing. The second electrically non-conductive moulded housing may cover the second integrated circuit die similarly to the first electrically non-conductive moulded housing covering the first integrated circuit die. However, as the second integrated circuit die may be mounted on the first electrically conductive material rather than the substrate, the first electrically conductive material may replace the substrate. In other words, the second electrically non-conductive moulded housing may completely cover the parts of second integrated circuit die not in contact with the first electrically conductive material.

Usually, the second electrically conductive material, the first electrically conductive material and the substrate enclose the second integrated circuit die and the second wire. This enables improved protection against interference to or from the second integrated circuit die and the second wire.

The third electrically non-conductive moulded housing may cover the third integrated circuit die. Likewise, in the method, moulding the third electrically non-conductive moulded housing may comprise covering the third integrated circuit die by the third electrically non-conductive moulded housing. The third electrically non-conductive moulded housing may cover the third integrated circuit die similarly to the second electrically non-conductive moulded housing covering the second integrated circuit die, except the second electrically conductive material may replace the first electrically conductive material. In other words, the third electrically non-conductive moulded housing may completely cover the parts of third integrated circuit die not in contact with the second electrically conductive material.

Usually, the third electrically conductive material, the second electrically conductive material and the substrate enclose the third integrated circuit die and the fourth wire. This enables improved protection against interference to or from the third integrated circuit die and the fourth wire.

The first, second and/or fourth wires may be a first bond wire, a second bond wire and/or a fourth bond wire respectively. As such, the first, second and/or fourth wires may be arranged externally to the first, second and/or third integrated circuit dies respectively. Typically, the first electrical terminal of the substrate is arranged on a surface of the substrate on which the first integrated circuit die is mounted, and the first electrical terminal of the first integrated circuit die is arranged on a surface of the first integrated circuit die facing in the same direction as that surface of the substrate. In any event, the first wire may extend between the substrate and a surface of the first integrated circuit die facing away from the substrate. Typically, the first wire therefore extends over an edge of the first integrated circuit die. The second wire and the second integrated circuit die, and/or the fourth wire and the third integrated circuit die may be similarly arranged. It will also be appreciated that, in practice, there may be plural first wires, second wires and/or fourth wires coupling different first electrical terminals, second electrical terminals and/or third electrical terminals of the first integrated circuit die, second integrated circuit die and/or third integrated circuit die to different first electrical terminals, second electrical terminals and/or third electrical terminals of the substrate.

Likewise, the third and fifth wires may be a third bond wire and fifth bond wire respectively. Typically, the third electrical terminal of the second integrated circuit die is arranged on a surface of the second integrated circuit die facing in the same direction as a surface of the first electrically conductive material on which the second integrated circuit may be mounted. In any event, the third wire may extend between the first electrically conductive material and a surface of the first integrated circuit die facing away from the first electrically conductive material. Typically, the third wire therefore extends over an edge of the second integrated circuit die. The fifth wire and the third integrated circuit die may be similarly arranged.

The substrate may comprise a layer of electrically conductive material within an electrically non-conductive material. The layer of electrically conductive material may be coupled to the first electrically conductive material and/or the second electrically conductive material and/or the third electrically conductive material. Typically, the first integrated circuit die is located on the substrate in an area substantially coincident with an area of the layer of electrically conductive material. This enables improved protection against interference between the first integrated circuit die and components on a side of the substrate opposite to that on which the first integrated circuit die may be mounted.

The electronic device may comprise printed circuit board connection means for coupling the substrate to a printed circuit board. Likewise, the method may comprise providing printed circuit board connection means for coupling the substrate to a printed circuit board. This feature enables the electronic device to be ready for mounting on a printed circuit board. There is also provided an electronic apparatus comprising the electronic device mounted on a/the printed circuit board.

The first, second and/or third electrically conductive material may comprise a metal or a conductive polymer. Similarly, the method may comprise applying the first, second or third electrically conductive material to the surface of the first, second or third electrically non-conductive moulded housing respectively as a metal or a conductive polymer. Suitable metals are, for example, copper, iron or nickel.

There may be a first distance between the first wire and the first electrically conductive material which is substantially uniform over a majority of the length of the first wire. Likewise the method may comprise providing a first distance between the first wire and the first electrically conductive material which is substantially uniform over at least a majority of the length of the first wire.

This enables improved impedance matching and reduced signal attenuation, particularly in the case of very high frequency signals.

The electronic device may comprise a plurality of the first wires each coupling a respective one of a plurality of the first electrical terminals of the first integrated circuit die to a respective one of a plurality of the first electrical terminals, wherein the first distance between each of the first wires and the first electrically conductive material is substantially uniform over at least a majority of the length of each of the first wires. This enables improved impedance matching and reduced signal attenuation, particularly in the case of very high frequency signals.

There may be a substantially equal spacing between adjacent ones of the plurality of the first wires over at least a majority of the length of each of the first wires. This enables improved impedance matching and reduced signal attenuation, particularly in the case of very high frequency signals.

The electronic device may comprise means for coupling alternate ones of the plurality of the first wires to the reference voltage. This can enable improved impedance matching and shielding between those of the first wires that carry signals.

There may be a second distance between the second wire and the first electrically conductive material which is substantially uniform over at least a majority of the length of the second wire. This enables improved impedance matching and reduced signal attenuation, particularly in the case of very high frequency signals.

The electronic device may comprise a plurality of the second wires each coupling a respective one of a plurality of the second electrical terminals of the second integrated circuit die to a respective one of a plurality of the second electrical terminals, wherein the second distance between each of the second wires and the first electrically conductive material is substantially uniform over at least a majority of the length of each of the second wires. This enables improved impedance matching and reduced signal attenuation, particularly in the case of very high frequency signals.

There may be a substantially equal spacing between adjacent ones of the plurality of the second wires over at least a majority of the length of each of the second wires. This enables improved impedance matching and reduced signal attenuation, particularly in the case of very high frequency signals.

The electronic device may comprise means for coupling alternate ones of the plurality of the second wires to the reference voltage. This can enable improved impedance matching and shielding between those of the second wires that carry signals.

The first distance and the second distance may be substantially equal. This enables improved impedance matching and reduced signal attenuation, particularly in the case of very high frequency signals.

### BRIEF DESCRIPTION OF THE DRAWINGS

Preferred embodiments will now be described, by way of example only, with reference to the accompanying drawings, in which:

FIG. 1 is a schematic sectional view of an electronic apparatus comprising an electronic device according to a first embodiment of the present disclosure;

FIG. 2 is a schematic sectional view of an electronic apparatus comprising an electronic device according to another embodiment of the present disclosure;

FIG. 3 is a schematic sectional view of an electronic apparatus comprising an electronic device according to a further embodiment of the present disclosure;

FIG. 4 is a flow chart illustrating the steps of manufacturing an electronic device according to an embodiment of the present disclosure;

FIGS. 5A-I are schematic sectional views of an electronic device according to an embodiment of the present disclosure at successive stages of manufacture of the electronic device;

FIG. 6 a schematic sectional view of an electronic device according to a further embodiment of the present disclosure; and

FIG. 7 is a schematic cross-sectional view of the electronic device illustrated in FIG. 6.

### DETAILED DESCRIPTION OF PREFERRED EMBODIMENTS

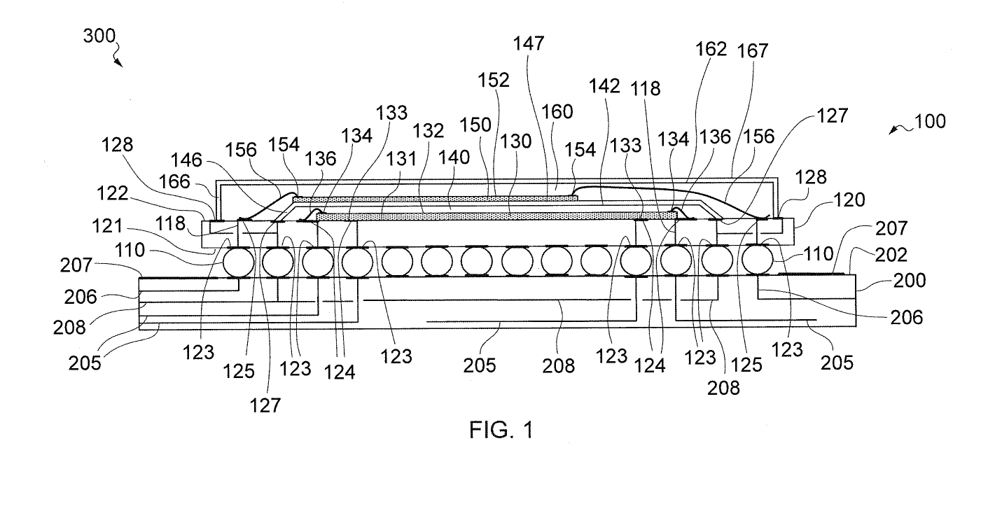

Referring to FIG. 1, an electronic apparatus 300 according to a first embodiment of the present disclosure comprises an electronic device 100 mounted on a printed circuit board (PCB) 200 by solder balls 110, such as a ball grid array. The solder balls 110 are located between an upper surface 202 of the PCB 200 and a lower surface of the electronic device 100, and provide electrical connections between the electronic device 100 and the PCB 200. The upper surface 202 of the PCB 200 is a surface of the PCB 200 on which the electronic device 100 is mounted, and the lower surface of the electronic device 100 faces the PCB 200.

The electronic device 100 comprises a substrate 120 made of an electrically non-conductive material. A lower surface 121 of the substrate 120 provides the lower surface of the electronic device 100. A first integrated circuit die 130 is mounted, for example by an adhesive such as a glue or a die attach film (DAF), on an upper surface 122 of the substrate 120. The upper surface 122 of the substrate 120 faces away from the solder balls 110 and the PCB 200. There are electrical connections between the first integrated circuit die 130 and the substrate 120 by first die lower electrical terminals 133 on a lower surface 131 of the first integrated circuit die 130. The lower surface 131 of the first integrated circuit die 130 faces the substrate 120. The first die lower electrical terminals 133 are in contact with some of substrate first upper electrical terminals 124 on the upper surface 122 of the substrate 120. There are additional electrical connections between the first integrated circuit die 130 and the substrate 120 by means of first die upper electrical terminals 134 on an upper surface 132 of the first integrated circuit die 130. The upper surface 132 of the first integrated circuit die 130 faces away from the substrate 120. The first die upper electrical terminals 134 are connected to others of the substrate first upper electrical terminals 124 on the upper surface 122 of the substrate 120 by first bond wires 136. The first bond wires 136 are attached to the first die upper electrical terminals 134 and the substrate first upper electrical terminals 124 by applying pressure and ultrasonic heating, such that the material from the first bond wires 136 penetrates to metal pads which are the first die upper electrical terminals 134 and the substrate first upper electrical terminals 124.

The first bond wires 136 are embedded in a first moulded housing 140 made of an electrically non-conductive material. In this embodiment, the first integrated circuit die 130 is also embedded in the first moulded housing 140. In other embodiments the first integrated circuit die 130 may be partially embedded in the first moulded housing 140, or fully or partially covered by the first moulded housing 140. A layer of a first electrically conductive material 146 is provided on an upper surface 142 of the first moulded housing 140. The upper surface 142 of the first moulded housing 140 faces away from the substrate 120. The first electrically conductive material 146 is coupled to substrate first reference terminals 127.

A second integrated circuit die 150 is mounted, for example by an adhesive, on an upper surface 147 of the first electrically conductive material 146. The upper surface 147 of the first electrically conductive material 146 faces away from the first moulded housing 140. There are electrical connections between the second integrated circuit die 150 and the substrate 120 by means of second die upper electrical terminals 154 on an upper surface 152 of the second integrated circuit die 150. The upper surface 152 of the second integrated circuit die 150 faces away from the first electrically conductive material 146. The second die upper electrical terminals 154 are connected to substrate second upper electrical terminals 125 on the upper surface 122 of the substrate 120 by second bond wires 156.

The second bond wires 156 are embedded in a second moulded housing 160 made of an electrically non-conductive material. In this embodiment, the second integrated circuit die 150 is also embedded in the second moulded housing 160. In other embodiments the second integrated circuit die 150 may be partially embedded in the second moulded housing 160, or fully or partially covered by the second moulded housing 160. Also embedded in the second moulded housing 160 are the first electrically conductive material 146 and the first moulded housing 140, and consequently also the first integrated die 130 and the first bond wires 136.

The substrate 120 comprises substrate conductors 118 providing electrical connections between the substrate first and second upper electrical terminals 124, 125 and respective substrate lower electrical terminals 123 and between the substrate first reference terminals 127 and respective substrate lower electrical terminals 123. The substrate lower electrical terminals 123 are in contact with the solder balls 110 which provide electrical connections between the substrate lower electrical terminals 123 and PCB conductors 205, 206, 207, 208 which are in or on the PCB 200.

The PCB conductors 205, 206, 207, 208 provide electrical connections between the solder balls 110 and a non-illustrated external device. In particular, the PCB conductors 205, 206, 207, 208 comprise: PCB first signal conductors 205 for conveying signals to or from the first integrated circuit die 130; PCB second signal conductors 206 for conveying signals to or from the second integrated circuit 150; a PCB shield conductor 207 for providing electrical shielding of the PCB first and second signal conductors 205, 206 from interference signals external to the electronic apparatus 300, or for providing electrical shielding of devices external to the electronic apparatus 300 from interference emitted by the PCB first or second signal conductors 205, 206; and a PCB reference conductor 208 for coupling the first electrically conductive material 146 to a reference voltage. The reference voltage may be at ground potential or may be a voltage positive or negative with respect to ground potential, such as a supply voltage. Either or both of the PCB shield conductor 207 and the PCB reference conductor 208 may be a ground plane, and preferably should provide a low impedance path for interference signals in order to reduce the impact of those signals. In the embodiment of FIG. 1, the PCB reference conductor 208 is located between the PCB first signal conductor 205 and the PCB second signal conductor 206 in order to reduce interference, or cross-talk, between these conductors. For example, the first integrated circuit die 130 may emit or receive high frequency signals that are prone to cause interference to other devices, and the second integrated circuit die 150 may process low level signals that are susceptible to these high frequency interfering signals. Protection against such interference occurring within the PCB is provided by positioning the PCB first and second signal conductors 205, 206 on opposite sides of the PCB reference conductor 208, and protection against such interference occurring between the first and second bonds wires 136, 156 and between the first and second integrated circuit die 130, 150 is provided by the first electrically conductive material 146.

In order to shield the second integrated circuit die 150 from interference generated externally to the electronic device 100, a second electrically conductive material 166 is provided on an upper surface 162 of the second moulded housing 160. The upper surface 162 of the second moulded housing 160 faces away from the second integrated circuit die 150. In FIG. 1, the second electrically conductive material 166 is coupled to the PCB reference conductor 208 by means of substrate second reference terminals 128 and associated ones of the substrate conductors 118 and solder balls 110.

The embodiment described with reference to FIG. 1 is particularly suitable in circumstances where the second integrated circuit die 150 is to be shielded from signals emitted by the first integrated circuit die 130. For example, the first integrated circuit die 130 may comprise a fast digital processing system containing a central processing unit (CPU) and memory, a power management unit, or a high power amplifier such as a radio frequency amplifier, an audio class D amplifier or a motor driver. Potentially interfering signals passing to and from the first integrated circuit die 130 are conducted through inner ones of the solder balls 110 and through the PCB first signal conductors 205 which are positioned relatively low in the PCB 200, and potentially susceptible signals passing to and from the second integrated circuit die 150 are conducted through outer ones of the solder balls 110 and through the PCB second signal conductors 206 which are positioned relatively high in the PCB 200, the PCB first and second signal conductors 205, 206 being separated by the PCB reference conductor 208.

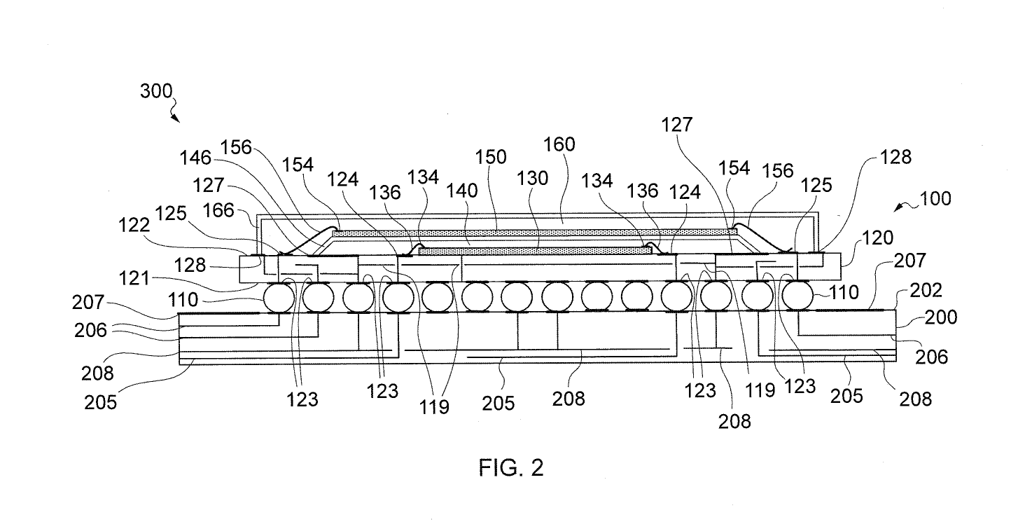

The embodiment illustrated in FIG. 2 will now be described. Elements of the embodiments illustrated in FIGS. 1 and 2 having the same name and function also have the same reference numerals and will not be described again. Only the differences of significance to the disclosure are described below.

The embodiment illustrated in FIG. 2 comprises a substrate reference conductor 119 within the substrate 120. In this embodiment, the substrate reference conductor 119 is coupled to the first electrically conductive material 146 by the substrate first reference terminals 127. The substrate first reference terminals 127 are coupled to the PCB reference conductor 208 by some of the substrate lower electrical terminals 123 and associated solder balls 110. The substrate reference conductor 119 provides additional shielding of the first integrated circuit die 130 and reduces coupling of interference signals between the solder balls 110 and the first integrated circuit die 130, and between and the PCB second signal conductors 205 and the first integrated circuit die 130.

The embodiment described with reference to FIG. 2 is particularly suitable in circumstances where the first integrated circuit die 130 is to be shielded from signals emitted by the second integrated circuit die 150. For example, the second integrated circuit die 150 may comprise a fast digital processing system containing a central processing unit (CPU) and memory, a power management unit, or a high power amplifier such as an radio frequency amplifier, an audio class D amplifier or a motor driver. Potentially interfering signals passing to and from the second integrated circuit die 150 are conducted through outer ones of the solder balls 110 and through the PCB second signal conductors 206 which are positioned relatively high in the PCB 200, and potentially susceptible signals passing to and from the first integrated circuit die 130 are conducted through inner ones of the solder balls 110 and through the PCB first signal conductors 205 which are positioned relatively low in the PCB 200. The PCB first and second signal conductors 205, 206 are separated by the PCB reference conductor 208.

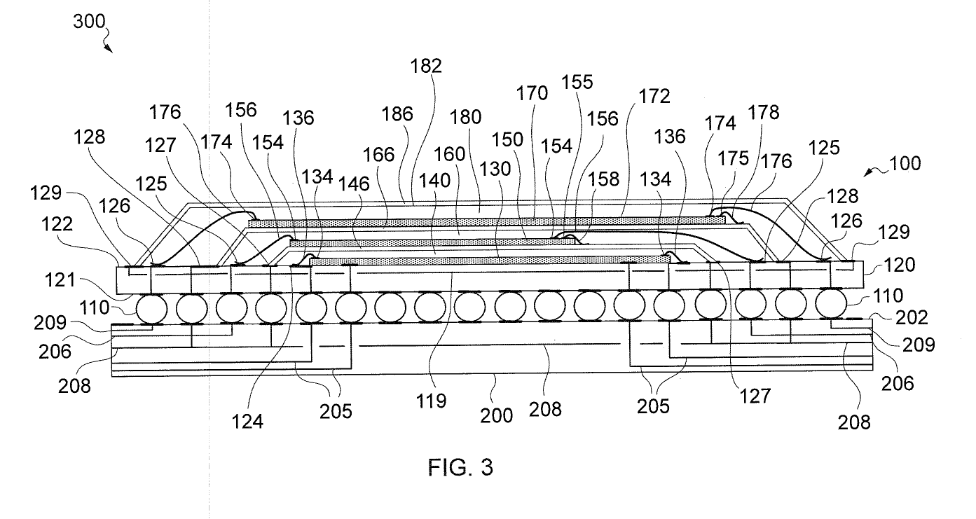

The embodiment illustrated in FIG. 3 will now be described. Elements of the embodiments illustrated in FIGS. 1, 2 and 3 having the same name and function also have the same reference numerals and will not be described again. Only the differences of significance to the disclosure are described below.

A third integrated circuit die 170 is mounted, for example by an adhesive, on an upper surface 167 of the second electrically conductive material 166. The upper surface 167 of the second electrically conductive material 166 faces away from the second moulded housing 160. There are electrical connections between the third integrated circuit die 170 and the substrate 120 by means of third die upper electrical terminals 174 on an upper surface 172 of the third integrated circuit die 170. The upper surface 172 of the third integrated circuit die 170 faces away from the second electrically conductive material 166. The third die upper electrical terminals 174 are connected to substrate third upper electrical terminals 126 on the upper surface 122 of the substrate 120 by third bond wires 176. In addition, the second integrated circuit die 150 is coupled to the first electrically conductive material 146 by means of second die reference terminals 155 and second reference bond wires 158, and the third integrated circuit die 170 is coupled to the second electrically conductive material 166 by means of third die reference terminals 175 and third reference bond wires 178.

The third integrated circuit die 170, the third bond wires 176 and the third reference bond wires 178 are embedded in a third moulded housing 180 made of an electrically non-conductive material. In other embodiments the third integrated circuit die 170 may be partially embedded in the third moulded housing 180, or fully or partially covered by the third moulded housing 180. Also embedded in the third moulded housing 180 are the second electrically conductive material 166 and the second moulded housing 160, and consequently also the second integrated circuit die 150, the second bond wires 156, the second reference bond wires 158, the first electrically conductive material 146, the first moulded housing 140, the first integrated die 130 and the first bond wires 136.

In order to shield the third integrated circuit die 170 from interference generated externally to the electronic device 100, a third electrically conductive material 186 is provided on an upper surface 182 of the third moulded housing 180. The upper surface 182 of the third moulded housing 180 faces away from the third integrated circuit die 170. The third electrically conductive material 166 is coupled to the PCB reference conductor 208 by means of substrate third reference terminals 129 and associated ones of the substrate conductors 118 and solder balls 110.

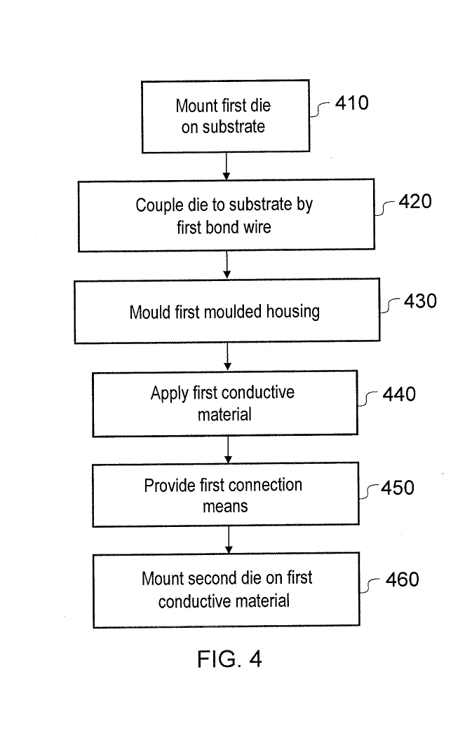

Referring to FIG. 4, a method of manufacturing the electronic device 100 commences at step 410 where the first integrated circuit die 130 is mounted on the substrate 120. By mounting the first integrated circuit die 130 on the substrate 120, the first die lower electrical terminals 133 may be coupled to some of the substrate first upper electrical terminals 124. At step 420, the first die upper electrical terminals 134 are coupled to others of the substrate first upper electrical terminals 124 by means of the first bond wires 136. At step 430, the first bond wires 136, and optionally the first integrated circuit die 130, are embedded in the first moulded housing 140, which is electrically non-conductive. At step 440, the first electrically conductive material 146 is applied to the upper surface 142 of the first moulded housing 140. At step 450, a first connection means may be provided for coupling the first electrically conductive material 146 to the reference voltage. For example, such a connection means may be the substrate first reference terminals 127. At optional step 460, the second integrated circuit die 150 is mounted on the upper surface 147 of the first electrically conductive material 146, such that the second integrated circuit die 150 is separated from the first integrated circuit die 130 and the first bond wires 136 by the first moulded housing 140 and the first electrically conductive material 146. That is, at least part of the first moulded housing 140 and the first electrically conductive material 146 lie between the first integrated circuit die 130 and the second integrated circuit die 150. In further non-illustrated optional steps, the second die upper electrical terminals 154 may be coupled to the substrate second upper electrical terminals 124 by means of the second bond wires 156, the second integrated circuit die 150 and the second bond wires 156 may be embedded in the second moulded housing 160, which is electrically non-conductive, the second electrically conductive material 166 may be applied to the upper surface 162 of the second moulded housing 160, and a connection means, such as the substrate second reference terminals 128, may be provided for coupling the second electrically conductive material 166 to the first reference voltage or a different reference voltage.

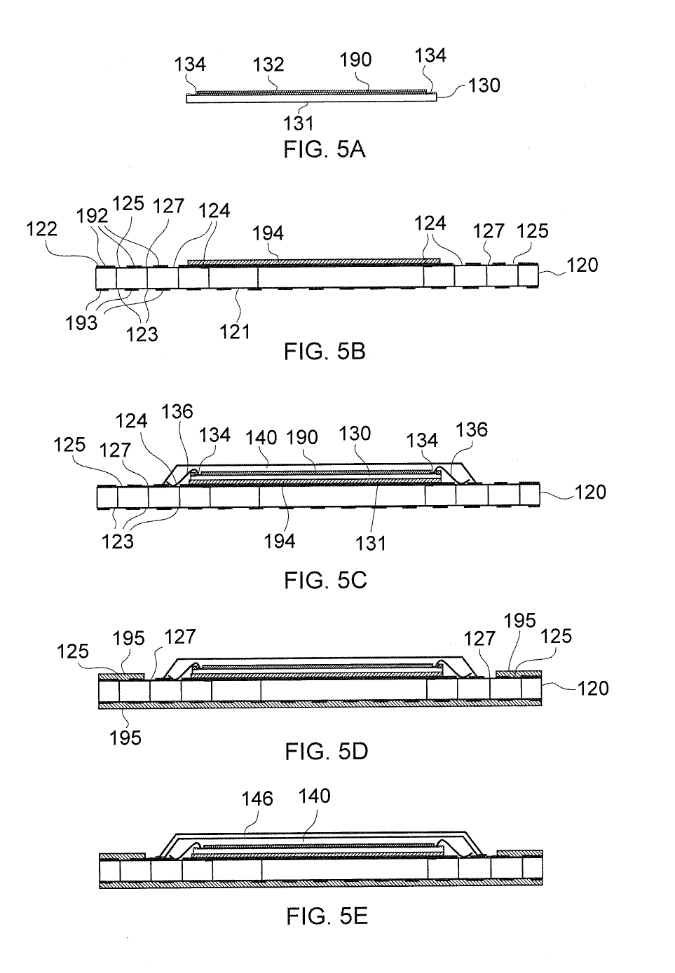

FIG. 5A to 5I illustrate stages in the manufacture of the electronic device 100 illustrated in FIG. 1. In FIG. 5A, there is illustrated the first integrated circuit die 130 and on its upper surface 132 a die passivation layer 190 is provided. There are gaps in the die passivation layer 190 at positions where the first integrated circuit die 130 has on its upper surface 132 the first die upper electrical terminals 134, such as bonding pads.

In FIG. 5B there is illustrated the substrate 120 having on its lower surface 121 the substrate lower electrical terminals 123 and on its upper surface 122 the substrate first and second upper electrical terminals 124, 125 and the substrate first reference terminals 127. The substrate third upper electrical terminals 126 and the substrate second and third reference terminals 128, 129 may also be present, but are not illustrated in FIGS. 5A to 5I. The substrate lower electrical terminals 123 are coupled to the substrate first and second upper electrical terminals 124, 125 and the substrate first reference terminals 127 by means of the substrate conductors 118 within the substrate 120. An upper solder mask 192 is deposited on the upper surface 122 of the substrate 120, and a lower solder mask 193 is deposited on the lower surface 121 of the substrate 120, these having gaps at the positions of the substrate first and second upper electrical terminals 124, 125, the substrate first reference terminals 127, and the substrate lower electrical terminals 123. A first layer of adhesive 194 is applied on an upper surface of the upper solder mask 192. The upper surface of the upper solder mask 192 faces away from the substrate 120.

At the stage illustrated in FIG. 5C, the lower surface 131 of the first integrated circuit die 130 has been brought into contact with the first layer of adhesive 194, the first die upper electrical terminals 134 have been coupled to some of the substrate first upper electrical terminals 124 by means of the first bond wires 136, and the first integrated circuit die 130, the die passivation layer 190, the first bond wires 136 and the substrate first upper electrical terminals 124 to which the first bond wires 136 are coupled are all embedded in the first moulded housing 140 by moulding the first moulded housing 140 over them.

At the stage illustrated in FIG. 5D, protection layers 195 have been applied to the lower surface of the assembly, covering the lower solder mask 193 and the substrate lower electrical terminals 123, and to the upper surface of the assembly, covering the exposed portions of the upper solder mask 192 and the substrate second upper electrical terminals 125, but not the substrate first reference terminals 127.

At the stage illustrated in FIG. 5E, the first electrically conductive material 146 has been deposited on the upper surface 142 of the first moulded housing 140 such that it is coupled to the substrate first reference terminals 124, which are adjacent to the first moulded housing 140. The first electrically conductive material 146 may be deposited by, for example, vacuum deposition. Next, the protection layers 195 are removed, as illustrated in FIG. 5F.

At the stage illustrate in FIG. 5G, a second layer of adhesive 196 is applied to the upper surface 147 of the first electrically conductive material 146, the second integrated circuit die 150 is placed on the second layer of adhesive 196, and the second die upper electrical terminals 154 are coupled to the substrate second upper electrical terminals 125 by means of the second bonds wires 156. Next, the second moulded housing 160 is moulded to embed the second integrated circuit die 150, the second bond wires 156, the first electrically conductive material 146 and the first moulded housing 140, including all the elements embedded in the first moulded housing 140, as illustrated in FIG. 5H. Finally, as illustrated in FIG. 5I, the solder balls 110 are attached to the substrate lower electrical terminals 123.

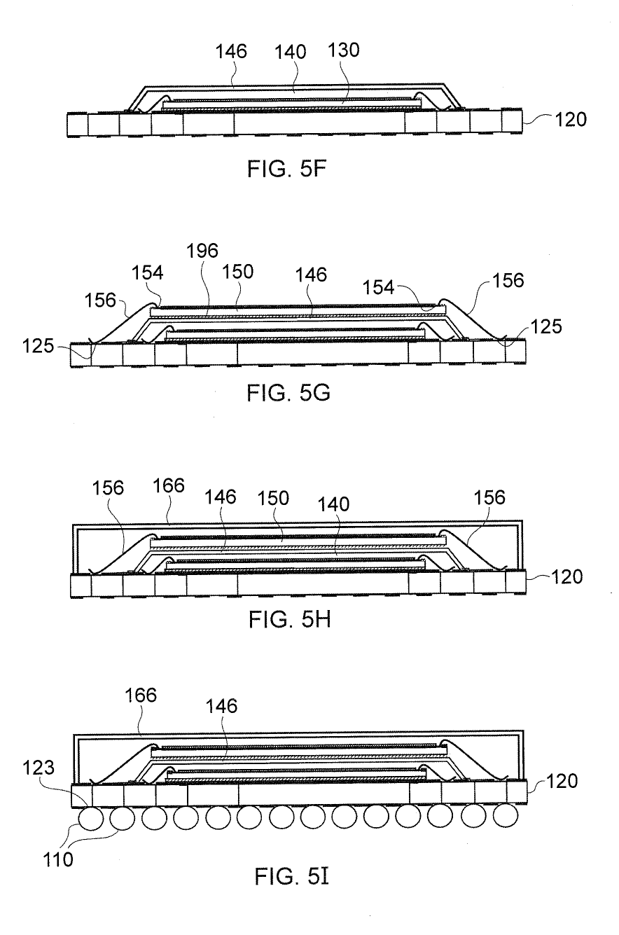

Referring to FIG. 6, there is illustrated an embodiment of the electronic device in which there is a substantially uniform first distance between each of the first wires 136 and the first electrically conductive material 146 over a majority of the length of the first wires 136. In other words, each of the first wires 136 and the first electrically conductive material 146, or more specifically the surface of the first electrically conductive material 146 facing the first wires 136, are substantially parallel over a majority of the length of the first wires 136. This majority may be at least 70%, or at least 80% or at least 90%, and preferably 100%, of the length of the first wires 136. The greater this majority, the greater the improvement in impedance matching that is possible. Such a substantially uniform first distance may be provided by moulding the upper surface 142 of the first moulded housing 140 to have a shape corresponding to the shape of the first bond wires 136, prior to depositing the first electrically conductive material 146 on the upper surface 142 of the first moulded housing 140. Other reference numerals in FIG. 6 have the same meaning as in FIGS. 1 to 5. The solder balls 110 and the PCB 200, and the electrical connections through the substrate 120 to the PCB 200, illustrated in FIGS. 1 to 3, have been omitted from FIG. 6 for clarity.

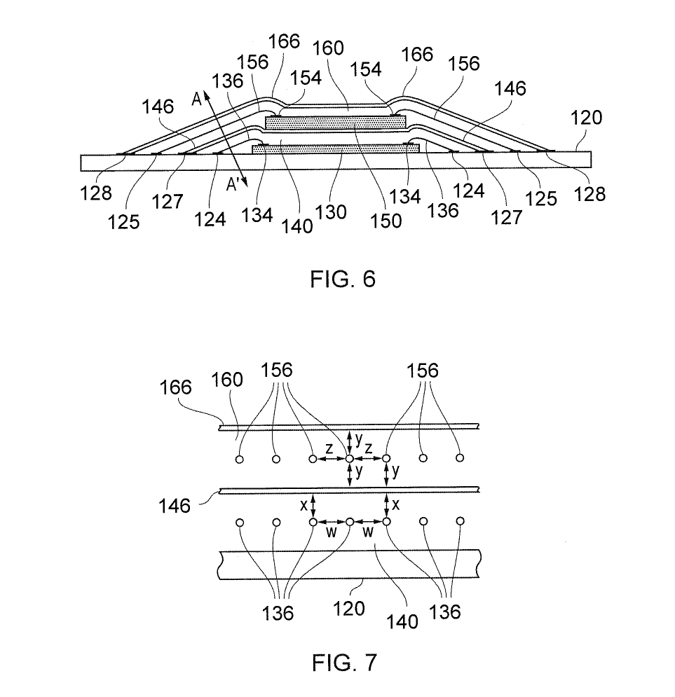

FIG. 7 illustrates a cross-sectional view along the line A-A′ in FIG. 6. A plurality of the first wires 136 are arranged in a row in the first electrically non-conductive moulded housing 140 between the substrate 120 and the first electrically conductive material 146 and each of the first wires 136 is the first distance, denoted x in FIG. 7, from the first electrically conductive material 146. In addition, adjacent ones of the first wires 136 are substantially parallel, that is, are spaced apart by a substantially equal distance, denoted w in FIG. 7, over a majority of the length of each of the first wires 136. Alternate ones of the plurality of the first wires 136 arranged in the row are coupled to the reference voltage by means of respective ones of the first electrical terminals 124.

Referring again to FIG. 6, there is a substantially uniform second distance between each of the second wires 156 and the first electrically conductive material 146 over a majority of the length of the second wires 156. In other words, each of the second wires 156 and the first electrically conductive material 146, or more specifically the upper surface 147 of the first electrically conductive material 146 facing the second wires 156, are substantially parallel over a majority of the length of the second wires 156. This majority may be at least 70%, or at least 80% or at least 90%, and preferably 100%, of the length of the second wires 156. The greater this majority, the greater the improvement in impedance matching that is possible. Such a substantially uniform second distance may be provided by moulding the upper surface 142 of the first moulded housing 140 to have a shape corresponding to the shape of the second bond wires 156, prior to depositing the first electrically conductive material 146 on the upper surface 142 of the first moulded housing 140, or forming the shape of the second bond wires 156 to correspond to the shape of the first electrically conductive material 146 deposited on the upper surface 142 of the first moulded housing 140.

In FIG. 7, the second distance between the second wires 156 and the first electrically conductive materials 146 is denoted y. In the illustrated embodiment, the second distance between the second wires 156 and the first electrically conductive material 146 is substantially equal to the first distance between the first wires 136 and the first electrically conductive material 146, that is the first and second wires 136, 156 are equidistant from the first electrically conductive material 146, which can improve impedance matching. However, in other embodiments the first and second distances may differ.

The second wires 156 illustrated in FIGS. 6 and 7 each couple a respective one of the second die upper electrical terminals 154 of the second integrated circuit die 150 to a respective one of the substrate second upper electrical terminals 125. Adjacent ones of the second wires 156 are substantially parallel, that is, are spaced apart by a substantially equal distance, denoted z in FIG. 7. Preferably, the equal spacing w between the adjacent ones of the first wires 136 is substantially equal to the equal spacing z between the adjacent ones of the second wires 156. This can improve impedance matching.

The second wires 156 of the electronic device illustrated in FIGS. 6 and 7 are arranged in a row, and alternate ones of the second wires 156 in the row are coupled to the reference voltage by means of the substrate second upper electrical terminals 125. This can improve the shielding of the intermediate ones of the second wires 156 which may be arranged for conveying signals. There is a substantially uniform third distance between each of the second wires 156 and the second electrically conductive material 166 over a majority of the length of the second wires 156. In other words, each of the second wires 156 and the second electrically conductive material 166, or more specifically the upper surface 162 of the second moulded housing 160 facing the second wires 156, are substantially parallel over a majority of the length of the second wires 156. This majority may be at least 70%, or at least 80% or at least 90%, and preferably 100%, of the length of the second wires 156. The greater this majority, the greater the improvement in impedance matching that is possible. Such a substantially uniform third distance may be provided by moulding the upper surface 162 of the second moulded housing 160 to have a shape corresponding to the shape of the second bond wires 156, prior to depositing the second electrically conductive material 166 on the upper surface 162 of the second moulded housing 160. In the embodiment illustrated in FIGS. 6 and 7, the third distance is equal to the second distance, for improved impedance matching, and is denoted y, although in other embodiments the second and third distances need not be equal.

Although embodiments have been described in which the first integrated circuit die 130 is mounted on the substrate by an adhesive, and the second integrated circuit die 150 is mounted on the first electrically conductive material 146 by an adhesive, other methods of mounting may be employed. For example, the first integrated circuit die 130 may be mounted on the substrate by soldering using flip chip technology, in particular by solder balls or cupper pillars. An alternative to soldering in flip chip technology is the use of conductive glue.

Suitable electrically non-conductive materials for the first moulded housing and the second moulded housing are, for example, the epoxy compounds known as SMT-B1, SMT-B2 and CK 9000.

The first and second electrically conductive materials 146, 166 may be, for example, copper, nickel, iron or gold, or a conductive polymer, and may be applied to the first and second moulded housings by, for example vacuum deposition for the metals, or spraying for the conductive polymers. To facilitate application of first and second electrically conductive materials 146, 166, the first and second moulded housings 140, 160 may have sloping walls.

In the described embodiments, the electronic device 100 has been illustrated coupled to a PCB 200 by means of solder balls. This is intended to be illustrative, rather than limiting. In other embodiments the electronic device 100 may have a provision other than solder balls for being coupled to other elements, such as a PCB or another component. Such a provision may be, for example, a lead frame package, a pad grid array package, a pin grid array package or a land grid array package. Furthermore, the term PCB is intended to encompass any type of mechanical support providing interconnection of electrical components, and is not intended to be limiting to any particular type of PCB.

The example embodiments have been described for a particular orientation, by referring to upper and lower surfaces, upper and lower electrical terminals and upper and lower solder masks. Such orientation is solely for the purpose of facilitating description, and is not intended to by limiting. Any other orientation may be employed for manufacture of the electronic device 100, or for the electronic device 100 incorporated in the electronic apparatus 300.

Although embodiments have been described which incorporate two and three integrated circuit dies 130, 150, 170, in other embodiments a larger number of integrated circuit dies may be incorporated. For example, four or more integrated circuit dies may be stacked, and each integrated circuit die may be coupled to the substrate by means of one or more bond wires, each integrated circuit die may be covered by, including embedded in, a respective electrically non-conductive moulded housing, and each electrically non-conductive moulded housing may have a surface carrying an electrically conducting material.

Although embodiments have been described which comprise a small number of the first second and third bonds wires 136, 156, 176, other embodiments may comprise larger numbers of such bonds wires, for example two hundred to four hundred.

Other variations and modifications will be apparent to the skilled person. Such variations and modifications may involve equivalent and other features which are already known and which may be used instead of, or in addition to, features described herein. Features that are described in the context of separate embodiments may be provided in combination in a single embodiment. Conversely, features which are described in the context of a single embodiment may also be provided separately or in any suitable sub-combination.

It should be noted that the term “comprising” does not exclude other elements or steps, the term “a” or “an” does not exclude a plurality, a single feature may fulfill the functions of several features recited in the claims and reference signs in the claims shall not be construed as limiting the scope of the claims. It should also be noted that the Figures are not necessarily to scale; emphasis instead generally being placed upon illustrating the principles of the present disclosure.

1-21. (canceled)

22. An electronic device comprising:
a first integrated circuit die mounted on a substrate;
a first wire coupling a first electrical terminal of the first integrated circuit die to a first electrical terminal of the substrate;
a first electrically non-conductive moulded housing in which the first wire and the first integrated circuit die are embedded;
a first electrically conductive material on a surface of the first electrically non-conductive moulded housing, wherein the first electrically conductive material and the substrate in combination enclose the first integrated circuit die and the first wire;
first reference terminals configured to couple the first electrically conductive material to a reference voltage; and
a second integrated circuit die mounted on the first electrically conductive material and separated from the first wire by the first electrically conductive material.

23. The electronic device of claim 22 comprising:
a second wire coupling a second electrical terminal of the second integrated circuit die to a second electrical terminal of the substrate;
a second electrically non-conductive moulded housing in which the second wire is embedded;
a second electrically conductive material on a surface of the second electrically non-conductive moulded housing; and
second reference terminals configured to couple the second electrically conductive material to the reference voltage.

24. The electronic device of claim 23 wherein the second electrically non-conductive moulded housing covers the second integrated circuit die.

25. The electronic device of claim 22 further comprising a third wire coupling a third electrical terminal of the second integrated circuit die to the first electrically conductive material.

26. The electronic device of claim 25 wherein the third wire is embedded in the second electrically non-conductive moulded housing.

27. The electronic device of claim 23 further comprising a third integrated circuit die separated from the second wire by the second electrically conductive material.

28. The electronic device of claim 27 wherein the third integrated circuit die is separated from the first wire by the first electrically conductive material.

29. The electronic device of claim 27 wherein the third integrated circuit die is separated from the first wire by the second electrically conductive material.

30. The electronic device of claim 27 further comprising:
a fourth wire coupling a third electrical terminal of the third integrated circuit die to a third electrical terminal of the substrate;
a third electrically non-conductive moulded housing in which the fourth wire is embedded;
a third electrically conductive material on a surface of the third electrically non-conductive moulded housing; and
third reference terminals configured to couple the third electrically conductive material to the reference voltage.

31. The electronic device of claim 30 wherein the substrate comprises a layer of electrically conductive material within an electrically non-conductive material.

32. The electronic device of claim 31 wherein the layer of electrically conductive material is coupled to one or more of the first electrically conductive material, the second electrically conductive material, and the third electrically conductive material.

33. The electronic device of claim 22 wherein a first distance between the first wire and the first electrically conductive material is substantially uniform over at least a majority of the length of the first wire.

34. The electronic device of claim 33 further comprising a plurality of the first wires, each coupling a respective one of a plurality of the first electrical terminals of the first integrated circuit die to a respective one of a plurality of the first electrical terminals, wherein the first distance between each of the first wires and the first electrically conductive material is substantially uniform over at least a majority of the length of each of the first wires.

35. The electronic device of claim 34 comprising a substantially equal spacing between adjacent ones of the plurality of the first wires over at least a majority of the length of each of the first wires.

36. The electronic device of claim 34 wherein respective ones of the first electrical terminals are configured to couple alternate ones of the plurality of the first wires to the reference voltage.

37. The electronic device of claim 33 wherein a second distance between the second wire and the first electrically conductive material is substantially uniform over at least a majority of the length of the second wire.

38. The electronic device of claim 37 further comprising a plurality of the second wires each coupling a respective one of a plurality of the second electrical terminals of the second integrated circuit die to a respective one of a plurality of the second electrical terminals, and wherein the second distance between each of the second wires and the first electrically conductive material is substantially uniform over at least a majority of the length of each of the second wires.

39. The electronic device of claim 38 comprising a substantially equal spacing between adjacent ones of the plurality of the second wires over at least a majority of the length of each of the second wires.

40. The electronic device of claim 38 wherein the second electrical terminals are configured to couple alternate ones of the plurality of the second wires to the reference voltage.

41. The electronic device of claim 38 wherein the first distance and the second distance are substantially equal.

42. A method of manufacturing an electronic device, the method comprising:
mounting a first integrated circuit die on a substrate;
providing a first wire coupling a first electrical terminal of the first integrated circuit die to a first electrical terminal of the substrate;
moulding a first electrically non-conductive moulded housing to embed the first wire and the first integrated circuit die;
applying a first electrically conductive material to a surface of the first electrically non-conductive moulded housing, wherein the first electrically conductive material and the substrate in combination enclose the first integrated circuit die and the first wire;
providing first reference terminals configured to couple the first electrically conductive material to a reference voltage; and
mounting a second integrated circuit die on the first electrically conductive material, wherein the second integrated circuit die is separated from the first wire by the first electrically conductive material.
